(19) United States
(12) Patent Application Publication
(10) Pub. No.: US 2024/0292574 A1
(43) Pub. Date: Aug. 29, 2024

(54) SYSTEM AND METHOD FOR COOLING DATA CENTERS AND ENERGY RECOVERY

(71) Applicant: Jason Todd ROTH, Orlando, FL (US)

(72) Inventor: Jason Todd ROTH, Orlando, FL (US)

(21) Appl. No.: 18/585,523

(22) Filed: Feb. 23, 2024

Related U.S. Application Data
(60) Provisional application No. 63/448,041, filed on Feb. 24, 2023.

(51) Int. Cl. H05K 7/20

(52) U.S. Cl. CPC H05K 7/20818; H05K 7/20318; H05K 7/20327

(57) ABSTRACT

A system for cooling a data center and energy recovery includes at least one electronics cabinet having electronics, a heat exchanger tank having heat exchanger piping, and closed loop nitrogen gas piping coupling the at least one electronics cabinet to the heat exchanger piping and configured to recirculate nitrogen gas. Heated nitrogen gas from the at least one electronics cabinet enters the heat exchanger tank via the closed loop piping, which causes the liquid nitrogen to vaporize. The system also includes an engine, a generator coupled to the engine, and outlet piping coupled to a top portion of the heat exchanger tank and to the engine. Energy from the vaporized nitrogen is utilized to drive the engine, which generates rotary motion to drive the generator to produce electricity. The system includes a condenser coupled to the engine to collect the nitrogen gas exiting the engine to repeat the cycle.

### CROSS-REFERENCE TO RELATED APPLICATIONS

This application claims the benefit of U.S. provisional patent application No. 63/448,041 filed Feb. 24, 2023, which is hereby incorporated herein in its entirety.

### TECHNICAL FIELD

The present invention relates to the field of data centers, and, more particularly, to a system and method for cooling data centers and energy recovery.

### BACKGROUND

Information Technology (IT) equipment refers to various hardware components and devices used in computing and telecommunications infrastructure to process, store, transmit, and manage digital information. IT equipment encompasses a wide range of devices and systems designed to support the needs of businesses, organizations, and individuals in managing data and conducting digital operations.

For example, servers are powerful computers designed to provide services, resources, and data storage to client computers and devices within a network. They can host applications, websites, databases, and other services critical to business operations. Networking equipment includes devices such as switches, routers, firewalls, and wireless access points used to establish and manage computer networks. Networking equipment enables communication and data transfer between devices within a network and between different networks. Storage systems consist of hardware components and software solutions designed to store and manage digital data. Examples include hard disk drives (HDDs), solid-state drives (SSDs), network-attached storage (NAS) devices, and storage area networks (SANs). Telecommunications equipment encompasses hardware devices used for voice and data communication, including telephones, mobile phones, modems, VoIP (Voice over Internet Protocol) devices, and teleconferencing systems.

In particular, data center equipment includes specialized hardware components and systems used to support the operation of data centers, such as uninterruptible power supplies (UPS), cooling systems, environmental monitoring devices, and rack cabinets. A cabinet to house IT equipment, often referred to as a server cabinet or server rack, is a specialized enclosure designed to securely store and organize various IT components and networking equipment within a data center or server room. These cabinets offer a structured framework for organizing IT equipment such as servers, switches, routers, storage arrays, and power distribution units (PDUs). They typically feature adjustable mounting rails or shelves to accommodate different sizes and form factors of equipment.

Cabinets provide physical protection for IT equipment against environmental hazards, such as dust, debris, and accidental damage. The enclosed design helps shield sensitive hardware from external elements and unauthorized access. Many server cabinets come with locking mechanisms to prevent unauthorized access and tampering with critical IT infrastructure. This helps safeguard sensitive data and ensures the integrity of the equipment housed within the enclosure. Server cabinets often include integrated cable management features such as cable trays, channels, and tie-off points. These help organize and route cables neatly, reducing clutter and minimizing the risk of cable damage or accidental disconnection.

Cabinets are typically designed with perforated doors, side panels, and roof vents to facilitate airflow and heat dissipation. Proper ventilation is essential for preventing equipment overheating and maintaining optimal operating conditions within the cabinet. The primary reason data centers need cooling is the heat generated by the IT equipment they house, including servers, storage devices, networking equipment, and other hardware. These devices generate significant amounts of heat while processing data and performing computations.

IT equipment operates optimally within a specific temperature range. If the temperature exceeds recommended levels, it can lead to performance degradation, component failure, and even permanent damage to the hardware. Cooling systems help maintain a stable and controlled temperature environment to ensure the reliability and longevity of the equipment.

Cooling systems help dissipate the heat generated by IT equipment by transferring it away from sensitive components and expelling it outside the data center environment. Without effective cooling, the ambient temperature within the data center can rise rapidly, leading to thermal issues and equipment failures.

Maintaining proper cooling conditions ensures that IT equipment operates at peak performance levels. High temperatures can cause processors to throttle their speed to prevent overheating, leading to reduced computational efficiency and slower response times for critical applications. Overheating poses a significant risk of downtime for data centers. When equipment fails due to heat-related issues, it can disrupt operations, cause data loss, and impact business continuity. Cooling systems help mitigate this risk by ensuring that temperatures remain within safe operating limits.

While cooling is necessary, data center operators strive to optimize cooling systems for energy efficiency. Efficient cooling solutions help reduce energy consumption and operating costs while maintaining the required temperature levels within the facility. Overall, effective cooling is crucial for the reliable operation, performance, and longevity of data center infrastructure. It allows data centers to support high-density computing environments while minimizing the risks associated with heat-related failures.

One way that the equipment is cooled is by mounting the electronic equipment within the cabinets on a raised floor in a common configuration. The ventilation and cooling system pressurizes the space below the electronic cabinets and acts as a large duct with vents through the raised floor in front of the cabinets. A shortcoming of the prior art ventilation system is that a substantial amount of energy is required to cool the space below the cabinets. Accordingly, what is needed in the art is a ventilation and cooling system and method that reduces the amount of energy to cool electronic equipment but at the same time increases the efficiency of cooling the equipment.

### SUMMARY

A system for cooling a data center and energy recovery is disclosed. The system includes at least one electronics cabinet having electronics, a heat exchanger tank having heat exchanger piping, and closed loop nitrogen gas piping coupling the at least one electronics cabinet to the heat exchanger piping and configured to recirculate nitrogen gas. Heated nitrogen gas from the at least one electronics cabinet enters the heat exchanger tank via the closed loop piping, which causes the liquid nitrogen to vaporize. The system also includes an engine, a generator coupled to the engine, and outlet piping coupled to a top portion of the heat exchanger tank and to the engine. Energy from the vaporized nitrogen is utilized to drive the engine, which generates rotary motion to drive the generator to produce electricity.

The system may also include a condenser coupled to the engine and configured to collect the nitrogen gas exiting the engine, wherein the cooled liquid nitrogen will then be ready to again be heated by the heat exchanger tank to be vaporized and to repeat the cycle.

In a particular aspect, the engine may comprise a turbine engine. In another aspect, the engine may comprise a piston coupled to a crankshaft.

In yet another aspect, a method of energy recovery from a data center is also disclosed. The method includes providing at least one electronics cabinet configured to house electronic equipment that generates heat, coupling closed loop piping to the at least one electronics cabinet to a heat exchanger the heat exchanger piping, and coupling a heat exchanger tank to the closed loop piping. The method also includes partially filling the heat exchanger tank with liquid nitrogen. In addition, the method includes coupling outlet piping to a top portion of the heat exchanger tank, coupling an engine to the outlet piping, and coupling a generator to the engine. The method includes recirculating nitrogen gas through the closed loop piping and to the heat exchanger tank. Heated nitrogen gas from the at least one electronics cabinet enters the heat exchanger tank via the closed loop piping and causes at least a portion of the liquid nitrogen in the heat exchanger tank to vaporize. This in turn leads to driving the engine using the vaporized nitrogen, which generates motion to drive the generator to produce electricity.

### BRIEF DESCRIPTION OF THE DRAWINGS

FIG. 1 is a schematic of a system for cooling data centers and energy recovery in accordance with aspects of the disclosure;

FIG. 2 is a schematic of the system of FIG. 1;

FIG. 3 is a perspective view of heat exchanger pipe of FIG. 2 showing an inner conduit thereof;

FIG. 4 is a partial cross sectional view of the heat exchanger pipe;

FIG. 5 is a perspective view of a mixer that is configured to fit within the heat exchanger pipe; and

FIG. 6 is a schematic of air flow through a pressure box of a data center that houses electronics.

### DETAILED DESCRIPTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

A system and method for cooling data centers and energy recovery is disclosed herein that lowers the cooling energy carbon footprint. This is achieved by creating a circulating equilibrium of air temperature for data center equipment and reducing the need for traditional air conditioning that use coolant chemicals and gasses, high amounts of fresh water, and large amounts of energy. The system eliminates the influence of cross-contamination from microscopic particles and gasses that cause downtime to data center equipment. In addition, the system is configured to reclaim energy used by the electronics through a heat exchanger that generates electricity.

The other benefits of the system include the ability to control corrosion and to otherwise reduce negative environmental impacts that data centers traditionally impart. As used herein, “data center” is a broad term used for any computer or IT environment including network rooms, LAN rooms, NOC rooms, etc. Data centers utilizing energy efficient low-conditioned or ambient air currently have an increased need for microchips and other computer components due to failures resulting from environmental corrosion. Creation of microchips and other computer components puts a strain on the environment as production of these items includes harsh chemicals, fumes and processes negatively impacting the environment. Corrosion is a major problem in the data center industry and this invention reduces and virtually eliminates the corrosion by controlling air content and eliminating the need for humidity to control the static as all components are grounded. Accordingly, the present invention leads to a longer lifespan of components and a reduction in environmental impacts from producing microchips and other components.

Unlike existing data centers, the system is configured so that data center equipment can reside in a harsh environment such as on a vessel at sea or any other environment subject to harsh IAQ (Indoor Air Quality).

In addition, current data centers are limited to the blower systems that plume cooling air from servers at the bottom to the servers vertically positioned at the top. The cooling air must not too be blown too quickly, otherwise the cooling air bypasses servers at the bottom to the reach the servers at the top. This limits the maximum height of the stackability of equipment to around seven feet. This invention solves that shortcoming and is virtually unlimited in stacking of servers vertically. Accordingly, the present invention significantly reduces the footprint of data centers by taking advantage of upward facility infrastructure. This is an important feature in downtown city sectors and areas where building sprawl is limited.

The system can achieve these advances due in part to a heat exchanger tank that is partially filled with liquid nitrogen. Nitrogen gas that has been heated by the electronics in the data center is circulated through the heat exchanger tank by piping. The liquid nitrogen in the heat exchanger tank vaporizes in response to the heat, which the vaporized nitrogen is used to drive an engine to generate electricity as described below.

The heat exchanger piping is comprised of highly conductive metal or thermal plastic that can withstand low temperatures (−195.8° C.). The piping may include mechanical mixing elements to enhance the heat exchange between the liquid nitrogen within the heat exchanger tank and the heated nitrogen gas in the piping. The heat loss cools the piping, which simultaneously vaporizing the liquid nitrogen in the tank for the pressure to drive the engine.

The system also includes a pressure box, which can be mounted to traditional computer cabinet. The pressure box houses electronic equipment and is sealed so it can stay pressurized as it connects to an intake pipe and an exhaust pipe that are coupled to the piping to form a closed loop circulation system. Accordingly, the system continues to move radiating electrons away from the chipset of the equipment housed inside the pressure box, into the closed loop exhaust pipe. The exhaust heat from the electronics is captured into the exhaust pipe that is coupled to the heat exchanger piping.

The air flowing through the closed loop circulation system may be nitrogen gas. Nitrogen gas is considered better than air for cooling certain applications due to its specific properties and characteristics. Nitrogen is an inert gas, which means it does not react with other substances under normal conditions. This inertness makes nitrogen suitable for cooling applications where the presence of reactive gases could lead to corrosion or degradation of components.

Nitrogen is typically very dry, with low moisture content. This dryness makes it suitable for data centers where moisture could cause damage or corrosion to sensitive electronic components. In addition, nitrogen gas has consistent properties and behaves predictably under different conditions. This consistency makes it easier to control and regulate cooling processes, ensuring stable and reliable performance in cooling systems. Nitrogen gas can also be produced and supplied with high levels of purity, free from contaminants and impurities that could adversely affect cooling performance or the integrity of sensitive equipment.

The system operates at a thermal equilibrium within the closed loop circulation. Since the computer equipment only typically radiates heat inside, moving electrons away from the interior of the electronics is a critical feature to maintain the thermal balance that is desired. Air movement velocity can be raised and lowered to balance the air speed and temperatures on the system. A fraction of the energy is needed to keep the velocity once thermal equilibrium is reached. This is a critical feature of the present invention in comparison to existing systems that are required to expend energy to mechanically push pressurized air through entire subfloors or rooms.

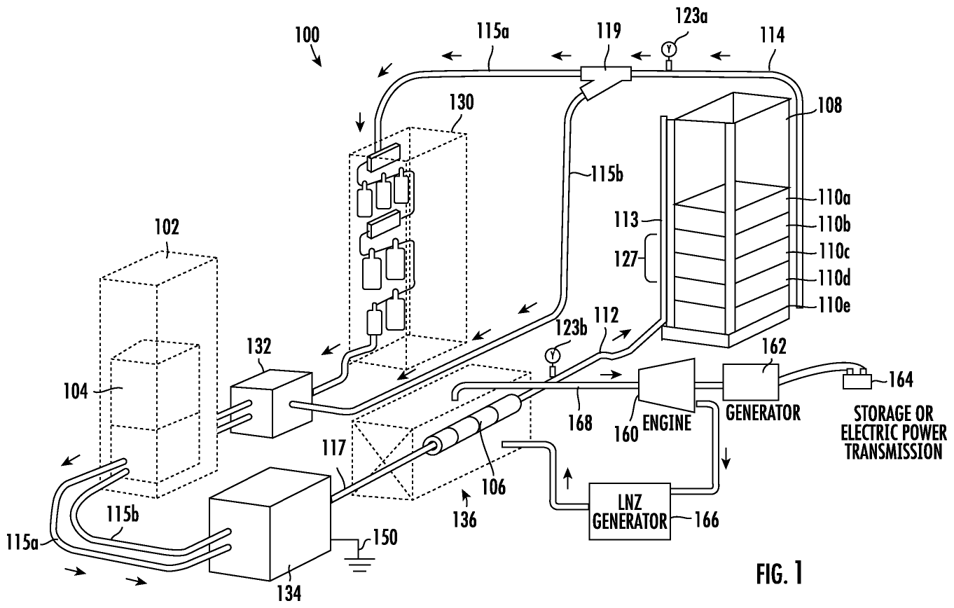

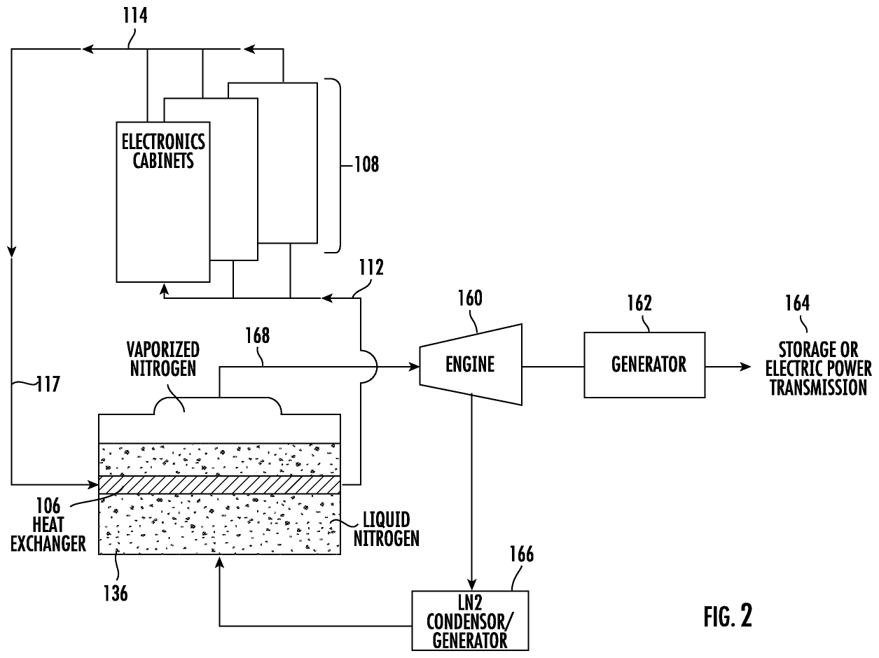

Referring now to FIGS. 1 and 2, the system for cooling data centers and energy recovery described above is depicted and generally designated 100. The system 100 includes an air handler 102 having a blower 104 coupled to an air ionizer/filter 134 that may also include a grounding wire 150 so that the system is grounded. The blower 104 is configured to force air through the conduits of the system 100 and supply nitrogen gas through piping 106 housed within a heat exchanger tank 136.

One or more electronics cabinets 108 are coupled to pressure boxes 110a-110e that house various electronic equipment. The electronic equipment generates heat that is required to be dissipated in order for the electronic equipment to continue to function properly. The pressure boxes 110a-110e are airtight housings that contain the electronic equipment.

The electronics cabinet 108 may have a respective supply pipe 112 that is coupled to piping 106 at an outlet of the heat exchanger tank 136 in order to supply cool air to the electronics cabinet 108 and the pressure boxes 110a-110e via manifold 113. An exhaust pipe 114 collects warm exhaust nitrogen gas from the pressure boxes 110a-110e to recirculate back through the heat exchanger tank 136 to cool the air before supplying back to the electronics cabinet 108. As those of ordinary skill in the art can appreciate, other suitable gases may be used other than nitrogen.

A diverter valve 119 may be downstream of a thermometer and/or hygrometer 123a and be in fluid communication with the exhaust pipe 114. Accordingly, the exhaust nitrogen gas may bypass the nitrogen generator 130 and flow through the system to the heat exchanger tank 136 via conduit 115b. The nitrogen generator 130 is configured to adjust a mixture of the air flowing through the system. Preferably the concentration of nitrogen is 78-80% or higher to prevent condensation and corrosion. Downstream of the nitrogen generator 130 is a storage box 132 that is used to help equalize the volume of nitrogen gas flowing through the system. Additional thermometers and/or hygrometers 123b, 123c may be in fluid communication with conduit 112a and 112b, respectively, downstream of the heat exchanger tank 136.

The energy reclamation aspect of the system includes outlet piping 168 coupled to the heat exchanger tank 136. The heated nitrogen gas enters the heat exchanger tank 136 via the piping 106, which causes the liquid nitrogen to boil or vaporize. The vaporized nitrogen is captured and collected at the top of the tank 136. The outlet piping 168 is coupled to an engine 160 where the energy from the vaporized nitrogen is utilized to drive the engine 160, which generates rotary motion. This rotary motion drives a generator 162 to produce electricity. The engine 160 may comprise a turbine or a piston/cylinder coupled to a crankshaft, for example.

After powering the engine 160, the nitrogen gas will exit the engine 160 and enter a condenser liquid/nitrogen generator 166. The cooled liquid nitrogen will then be ready to again be heated by the heat exchanger tank 136 to be vaporized and to repeat the cycle.

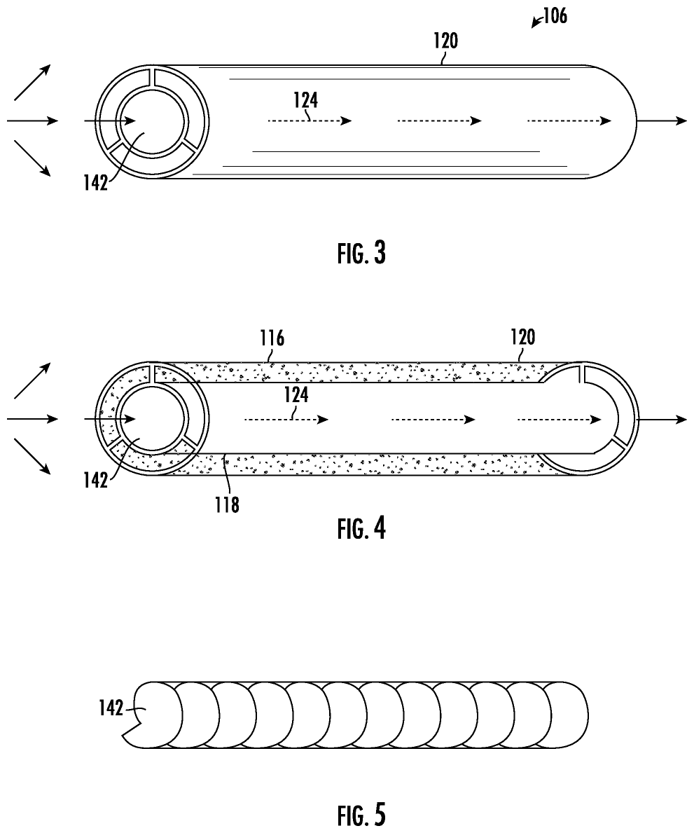

Referring now to FIGS. 3-4, a perspective view of the piping 106 within the heat exchanger tank 136 is shown. As those of ordinary skill in the art can appreciate the piping 106 may comprise one or more separate pipes passing through the heat exchanger tank 136 for the most efficient heat transfer. The piping 106 may include an inner tube 118 and a surrounding outer tube 120. Accordingly, an annular cavity may be formed between the inner and outer tubes 118, 120 and a heat conductive material carried by an outer surface of the inner tube 118.

The inner tube 118 also defines a pathway 124 for flow of the nitrogen gas. A mechanical mixer 142 is inserted within the inner tube 118 in order to slow the velocity of the flow. As a result the heat transfer of the heated nitrogen gas from the piping 106 to the cooled liquid nitrogen within the tank 136 is increased. As can be appreciated by those of ordinary skill in the art, the mixer 142 may include a variety of different sized and shaped baffles, or may have a helical configuration.

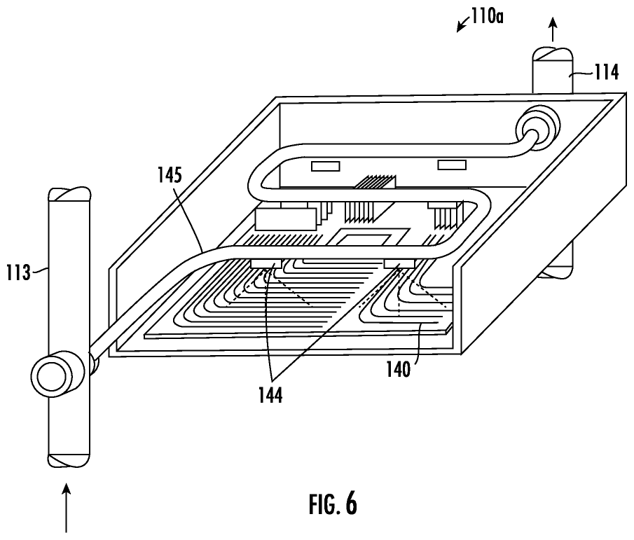

The pressure boxes 110a-110e house the computer electronics 140 or other equipment as shown in FIG. 6. The cooled nitrogen gas enters the pressure box 110a, for example, via manifold 113 into an air tube 145. A bypass hose 127 is configured to selectively control which pressure boxes of the plurality of pressure boxes 110a-110e are supplied with cooled nitrogen gas via the manifold 113. The air tube 145 may have one or more adjustable nozzles 144 configured to control the flow. The heated nitrogen air exits the pressure box 110a via exhaust pipe 114.

The heated exhaust nitrogen gas is recirculated back through the system to the heat exchanger tank to start the cycle again. The electron movement continues to balance into an equilibrium with minor temperature fluctuation and acceptable heat levels on the unit components.

A method of energy recovery from a data center is also disclosed. The method includes providing at least one electronics cabinet configured to house electronic equipment that generates heat, coupling closed loop piping to the at least one electronics cabinet to a heat exchanger the heat exchanger piping, and coupling a heat exchanger tank to the closed loop piping. The method also includes partially filling the heat exchanger tank with liquid nitrogen.

In addition, the method includes coupling outlet piping to a top portion of the heat exchanger tank, coupling an engine to the outlet piping, and coupling a generator to the engine. The method includes recirculating nitrogen gas through the closed loop piping and to the heat exchanger tank. As explained above, heated nitrogen gas from the at least one electronics cabinet enters the heat exchanger tank via the closed loop piping and causes at least a portion of the liquid nitrogen in the heat exchanger tank to vaporize. This in turn leads to driving the engine using the vaporized nitrogen, which generates motion to drive the generator to produce electricity.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A system for cooling a data center and energy recovery, the system comprising:
at least one electronics cabinet configured to house electronic equipment that generates heat;
a heat exchanger tank partially filled with liquid nitrogen and having heat exchanger piping;
closed loop piping coupling the at least one electronics cabinet to the heat exchanger piping and configured to recirculate nitrogen gas, wherein heated nitrogen gas from the at least one electronics cabinet enters the heat exchanger tank via the closed loop piping, which causes at least a portion of the liquid nitrogen in the heat exchanger tank to vaporize;
outlet piping coupled to a top portion of the heat exchanger tank;
an engine coupled to the outlet piping; and
a generator coupled to the engine, wherein energy from the vaporized nitrogen is utilized to drive the engine, which generates motion to drive the generator to produce electricity.

2. The system of claim 1, wherein the engine comprises a turbine engine.

3. The system of claim 1, wherein the engine comprises a piston coupled to a crankshaft.

4. The system of claim 1, further comprising a condenser coupled to the engine and configured to collect the nitrogen gas exiting the engine, wherein the cooled liquid nitrogen is configured to be recirculated and vaporized within the heat exchanger tank.

5. The system of claim 1, further comprising a check valve coupled to the outlet piping and configured to release vaporized nitrogen from the heat exchanger tank at a predetermined pressure.

6. The system of claim 1, further comprising a mechanical mixer within the heat exchanger piping configured to slow the velocity of the flow.

7. The system of claim 1, wherein the electronics cabinet comprising at least one pressure box configured to house the electronic equipment.

8. The system of claim 1, further comprising a thermometer or hygrometer in fluid communication with the closed loop piping downstream of the heat exchanger tank.

9. The system of claim 1, further comprising a nitrogen generator in fluid communication with the closed loop piping system and configured to adjust a mixture of gas.

10. The system of claim 9, wherein a concentration of nitrogen is 78-80% or higher to prevent condensation and corrosion.

11. A system for cooling a data center and energy recovery, the system comprising:
a heat exchanger tank at least partially filled with liquid nitrogen and having heat exchanger piping and outlet piping;
closed loop piping coupled to the heat exchanger piping and configured to be coupled to at least one electronics cabinet that generates heat;
an engine coupled to the outlet piping of the heat exchanger tank and configured to be driven by vaporized nitrogen generated from the heat from the closed loop piping coupled to the heat exhaust piping; and
a generator coupled to the engine wherein energy from the vaporized nitrogen is utilized to drive the engine, which in turn generates motion to drive the generator to produce electricity.

12. The system of claim 11, wherein the engine comprises a turbine engine or a piston coupled to a crankshaft.

13. The system of claim 11, further comprising a condenser coupled to the engine and configured to collect the nitrogen gas exiting the engine, wherein the cooled liquid nitrogen is configured to be recirculated and vaporized within the heat exchanger tank.

14. The system of claim 11, further comprising a check valve coupled to the outlet piping and configured to release vaporized nitrogen from the heat exchanger tank at a predetermined pressure.

15. The system of claim 11, further comprising a nitrogen generator in fluid communication with the closed loop piping system and configured to adjust a mixture of gas.

16. The system of claim 15, wherein a concentration of nitrogen is 78-80% or higher to prevent condensation and corrosion.

17. A method of energy recovery from a data center, the method comprising:
providing at least one electronics cabinet configured to house electronic equipment that generates heat;
coupling closed loop piping to the at least one electronics cabinet to a heat exchanger the heat exchanger piping;
coupling a heat exchanger tank to the closed loop piping, and partially filling the heat exchanger tank with liquid nitrogen;
coupling outlet piping to a top portion of the heat exchanger tank;
coupling an engine to the outlet piping;
coupling a generator to the engine;
recirculating nitrogen gas through the closed loop piping and to the heat exchanger tank where heated nitrogen gas from the at least one electronics cabinet enters the heat exchanger tank via the closed loop piping and causes at least a portion of the liquid nitrogen in the heat exchanger tank to vaporize; and
driving the engine using the vaporized nitrogen, which generates motion to drive the generator to produce electricity.

18. The method of claim 17, wherein the engine comprises a turbine engine or a piston coupled to a crankshaft.

19. The method of claim 17, wherein the heat exchanger piping has a mechanical mixer configured to slow the velocity of the flow.

20. The method of claim 17, further comprising providing a nitrogen generator in fluid communication with the closed loop piping system and configured to adjust a mixture of gas.
